(19) United States
(12) Patent Application Publication
(10) Pub. No.: US 2011/0193099 A1
(43) Pub. Date: Aug. 11, 2011

(54) SEMICONDUCTOR DEVICE

(75) Inventor: Shigeto HONDA, Tokyo (JP)

(73) Assignee: MITSUBISHI ELECTRIC CORPORATION, Chiyoda-ku (JP)

(21) Appl. No.: 12/882,699

(22) Filed: Sep. 15, 2010

(30) Foreign Application Priority Data
Feb. 10, 2010 (JP) 2010-027456

(51) Int. Cl. H01L 29/24; H01L 29/20

(52) U.S. Cl. 257/77; 257/76; 257/E29.104; 257/E29.089

(57) ABSTRACT

A semiconductor device according to the present invention includes: a low dielectric constant oxide film as an inorganic oxide film formed selectively on an n-type semiconductor substrate as a semiconductor substrate of a fist conductivity type; and anode electrodes as electrode layers formed on the n-type semiconductor substrate so as to sandwich the low dielectric constant oxide film therebetween, wherein the low dielectric constant oxide film is doped with an element for reducing a dielectric constant.

### BACKGROUND OF THE INVENTION

1. Field of the Invention

The present invention relates to a semiconductor device, and more particularly, to an insulating film under a field plate of a power semiconductor device.

2. Description of the Background Art

In recent years, power semiconductor devices have been required to have high breakdown voltage and large current characteristics along with the trend toward larger size and larger volume of applied equipment. In particular, the power semiconductor devices are required to have low saturation voltage for reducing power loss in a conduction state while causing extremely large current to flow. Further, when entering an off-state or at the time when a switch is turned off, the power semiconductor devices are required to have characteristics capable of withstanding a high reverse voltage applied across ends of a power device, that is, high breakdown voltage characteristics.

The breakdown voltage of a semiconductor device is determined by a depletion region of a pn junction. This is because most of the voltage applied to the pn junction is applied to a depletion region. It is known that this breakdown voltage is affected by a curvature of a depletion region. That is, in a planar junction, due to an electric field crowding effect in which an electric field is more concentrated on a part having a curvature than a flat portion, an electric field is concentrated on edge portions having a larger curvature compared with a plane junction. Accordingly, an avalanche breakdown is likely to occur at the edge portions, which reduces the breakdown voltage of the entire depletion region.

For example, the method of forming a field plate at an edge portion of a planar junction is known as the technique of improving the curvature of a depletion region to increase the breakdown voltage (see B. J. Baliga, “Power semiconductor devices”. 1996, pp. 100-102).

A surface potential is changed to control a curvature of a depletion layer in this method of forming a field plate, and a shape of the depletion layer extending from a substrate surface is adjusted by the voltage applied to the field plate. The filed plate is formed on an insulating film of a semiconductor substrate, and the thickness of the insulating film is generally required to he large for increasing breakdown voltage. Thus, the thickness of the insulating film under the field plate becomes larger along with an increase in breakdown voltage. That is, a gap between a semiconductor substrate and an insulating film when a semiconductor device is manufactured increases as the breakdown voltage becomes larger (see Japanese Patent Application Laid-Open No. 10-335631 and Japanese Patent Application Laid-Open No. 08-306937).

In a case where an insulating film under a field plate has a small thickness, an avalanche occurs at ends of the field plate, whereby the breakdown voltage of a device is reduced. Accordingly, the insulating film under the field plate is required to have a large thickness. However, the insulating film under the field plate becomes a gap in the wafer process, and when the thickness of the insulating film becomes larger, a number of problems are caused when manufacturing a semiconductor manufacturing apparatus, such as an occurrence of unevenness during resist application and a reduction in focus margin during photolithography.

### SUMMARY OF THE INVENTION

An object of the present invention is to provide a semiconductor device that reduces a gap in a wafer process while keeping a device breakdown voltage, to thereby suppress problems such as an occurrence of unevenness during resist application and a reduction in focus margin during photolithography.

A semiconductor device according to the present invention includes: an inorganic oxide film selectively formed on a semiconductor substrate of a first conductivity type; and electrode layers formed on the semiconductor substrate so as to sandwich the inorganic oxide film therebetween, wherein the inorganic oxide film is doped with an element for reducing a dielectric constant.

Accordingly, it is possible to keep device breakdown voltage with a thin oxide film and reduce a gap in a wafer process, to thereby suppress problems such as an occurrence of unevenness during resist application and a reduction in focus margin during photolithography.

These and other objects, features, aspects and advantages of the present invention will become more apparent from the following detailed description of the present invention when taken in junction with the accompanying drawings.

### BRIEF DESCRIPTION OF THE DRAWINGS

FIG. 1 is a cross-sectional view of a semiconductor device according to a first preferred embodiment;

FIGS. 2 to 5 are graphs showing simulation results of electric field distribution of a semiconductor device according to the underlying technology of the present invention;

FIGS. 6 and 7 are graphs showing simulation results of electric field distribution of the semiconductor device according to the first preferred embodiment;

FIG. 8 is a cross-sectional view of a semiconductor device according to a second preferred embodiment;

FIG. 9 is a graph showing simulation results related to breakdown voltage of the semiconductor device according to the second preferred embodiment;

FIG. 10 is a cross-sectional view of a semiconductor device according to a third preferred embodiment;

FIG. 11 is a cross-sectional view of a semiconductor device according to a fourth preferred embodiment; and

FIG. 12 is a cross-sectional view of the high breakdown voltage semiconductor device using a field plate structure that is the underlying technology of the present invention.

### DESCRIPTION OF THE PREFERRED EMBODIMENTS

FIG. 12 shows the underlying technology of the present invention that employs a field plate structure. Note that for the sake of convenience, an activation region of a diode is shown.

The left portion of FIG. 12 is an activation region of a device formed of an n-type semiconductor substrate 1 and a p-type anode region 2, and the right portion thereof is a breakdown voltage structure. The field plate structure is composed of a field oxide film 4, an anode electrode 5 being in contact with the p-type anode region 2, an n+ channel stopper region 3 of an n-type diffusion layer formed on a periphery of a substrate, and an anode electrode 6 being in contact with the n+ channel stopper region 3 so as to extend from the activation region to a device end (see Japanese Patent Application Laid-Open No. 08-306937).

In a blocking state, when a cathode electrode 7 and the n+ channel stopper region 3 are applied with a positive voltage in the state in which the anode electrode 5 is grounded, a main junction is reversely biased, whereby a depletion layer spreads. In FIG. 12, a state of the depletion layer is indicated by a depletion layer end 8. The anode electrode 5 extends on an end of the p-type anode region 2 through the field oxide film 4, and functions as a field plate. The potential of the anode electrode 5 is fixed to zero, and thus the depletion layer spreads more easily. and an electric field of a curved part of the end of the p-type anode region 2 on which an electric field is concentrated is mitigated, which makes it possible to ensure breakdown voltage. The feature of this structure resides in that high breakdown voltage is achieved in a small area.

Note that the field oxide film 4 needs to be formed to have a large thickness for achieving higher breakdown voltage as described above, and a gap due to the large thickness causes a problem in a wafer process. A first preferred embodiment of the present invention is directed to solve the above-mentioned problem.

(A. First Preferred Embodiment)

(A-1. Configuration)

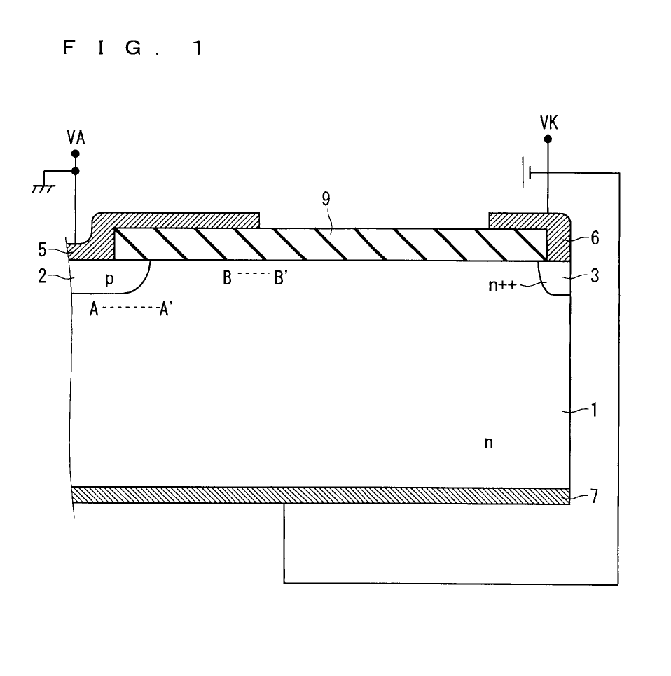

FIG. 1 is a cross-sectional view showing the configuration of a junction terminal of a high breakdown voltage semiconductor device according to the first preferred embodiment of the present invention. Note that for the sake of convenience, an activation region of a diode is shown.

The left portion of FIG. 1 is an activation region of a device formed of an n-type semiconductor substrate 1 and a p-type anode region 2, and the right portion thereof is a breakdown voltage structure. The field plate structure includes: the n-type semiconductor substrate 1; the p-type anode region 2 and an n+ channel stopper region 3 that are formed as first impurity regions on a surface of the n-type semiconductor substrate 1 to be apart from each other; a low dielectric constant oxide film 9 being an inorganic oxide film selectively formed in a region between the p-type anode region 2 and the n+ channel stopper region 3 on the n-type semiconductor substrate 1; anode electrodes 5 and 6 being electrode layers formed so as to he in contact with the p-type anode region 2 and the n+ channel stopper region 3, respectively, and sandwich the low dielectric constant oxide film 9 therebetween; and a cathode electrode 7 formed under the n-type semiconductor substrate 1.

(A-2. Operation) The configuration according to the present invention is different from that of a conventional case in that a dielectric constant of the low dielectric constant oxide film 9 is lower compared with the field oxide film 4 of FIG. 12. As the low dielectric constant oxide film 9, a silicon oxide film (SiO₂F having a dielectric constant of 3.4) in which, for example, fluorine is doped is used as an element for reducing a dielectric constant. Herienbelow, effects of breakdown voltage are compared between the field oxide film 4 and the low dielectric constant oxide film 9.

First, in a blocking state, when the cathode electrode 7 and the n+ channel stopper region 3 are applied with voltage in the state where the anode electrode 5 is grounded, a main junction is reversely biased, whereby a depletion layer spreads. The anode electrode 5 extends on an end of the p-type anode region 2 through the low dielectric constant oxide film 9 (field oxide film 4), and serves as a field plate.

The potential of the anode electrode 5 is fixed to zero, and thus a depletion layer spreads more easily, which mitigates an electric field of a curved part of an end of the p-type anode region 2 on which an electric field is concentrated. As a result, however, an electric field in the vicinity of the end of the field plate increases. In the field plate structure, an electric field in a blocking state increases in two regions of the curved part of the end of the p-type anode region 2 and the part in the vicinity of the end of the field plate.

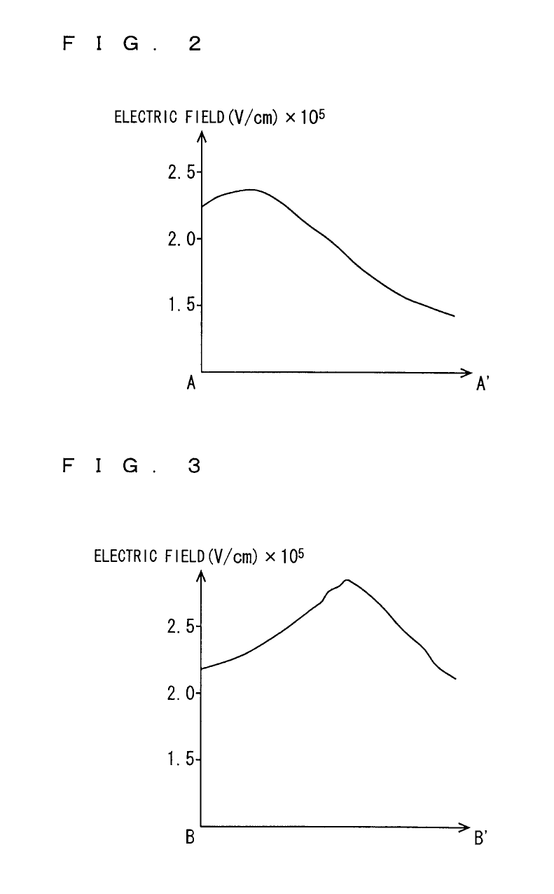

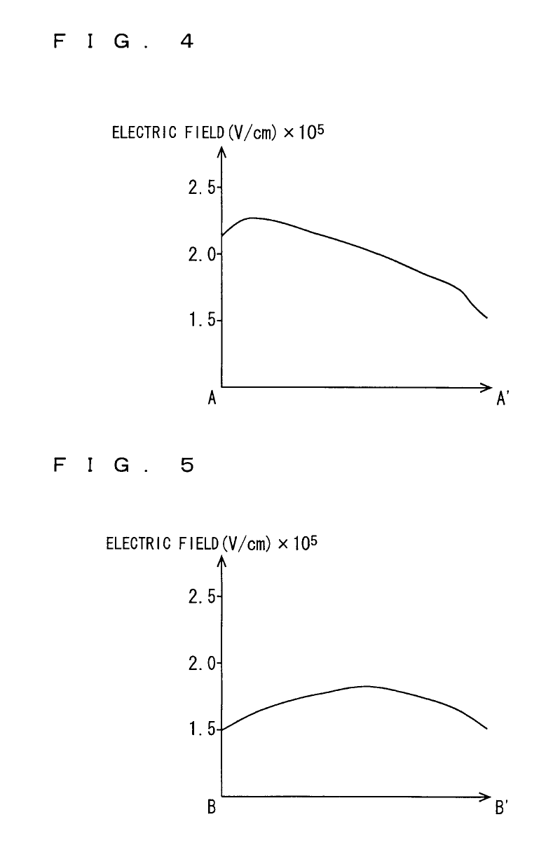

The electric field of the n-type semiconductor substrate 1 in the vicinity of the end of the field plate is dependent on the thickness of the oxide film as an insulating film under the field plate. The electric field of the n-type semiconductor substrate I in the vicinity of the end of the field plate increases as the thickness of the oxide film decreases. First, as to the high breakdown voltage semiconductor device shown in FIG. 12, there are shown simulation results of the electric field distribution (FIG. 2) of the part in the vicinity of the curved part of the end of the p-type anode region 2, which is A-A′ of FIG. 12, in a blocking state (during application of 500 V) and the electric field distribution (FIG. 3) of the part in the vicinity of the end of the field plate, which is B-B′ of FIG. 12, in the blocking state (during application of 500 V). Note that the concentration of the p-type anode region 2 is 2.0×10¹⁷ atoms/cm², the depth of the region whose distribution is shown is 7 μm, the concentration of the n-type semiconductor substrate 1 is 2.0×10¹⁴ atoms/cm³, and a silicon oxide film (having a dielectric constant of 3.9) having a thickness of 1 μm is used as the field oxide film 4.

As shown in FIGS. 2 and 3, the electric field is higher in the part in the vicinity of the end of the field plate than the part in the vicinity of the curved part of the end of the p-type anode region 2. An electric field of 2.5×10⁵ V/cm that is a critical electric field or more is applied to the part in the vicinity of the end of the field plate, where avalanche breakdown occurs.

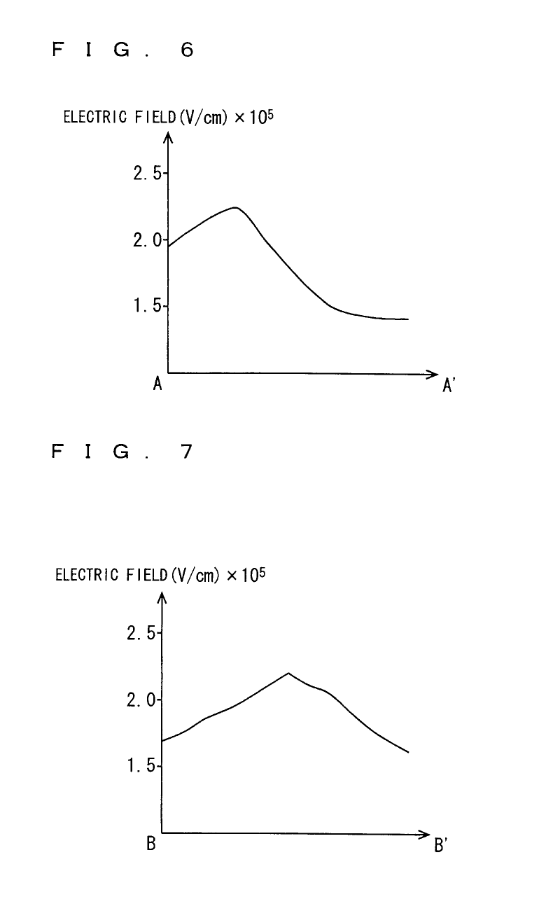

Next, FIG. 4 (electric field distribution of A-A′ of FIG. 12) and FIG. 5 (electric field distribution of B-B′ of FIG. 12) show the simulation results in a case where a silicon oxide film (having a dielectric constant of 3.9) having a thickness of 2 μm is used as the field oxide film 4. Note that other conditions are similar to those in the case of FIGS. 2 and 3.

It is revealed that by setting the thickness of the silicon oxide film used as the field oxide film 4 to 2 μm, an electric field in the vicinity of field plate end is mitigated and does not reach 2.5×10⁵ V/cm that is a critical electric field of silicon. The thickness of the field oxide film 4 as an insulating film under the field plate is increased as described above, whereby it is possible to mitigate an electric field in the vicinity of the end of the field plate. In this case, however, a larger thickness of the insulating film becomes a gap in a wafer process, which causes a large number of problems in manufacturing a semiconductor manufacturing apparatus, such as an occurrence of unevenness during resist application and a reduction in focus margin during photolithography.

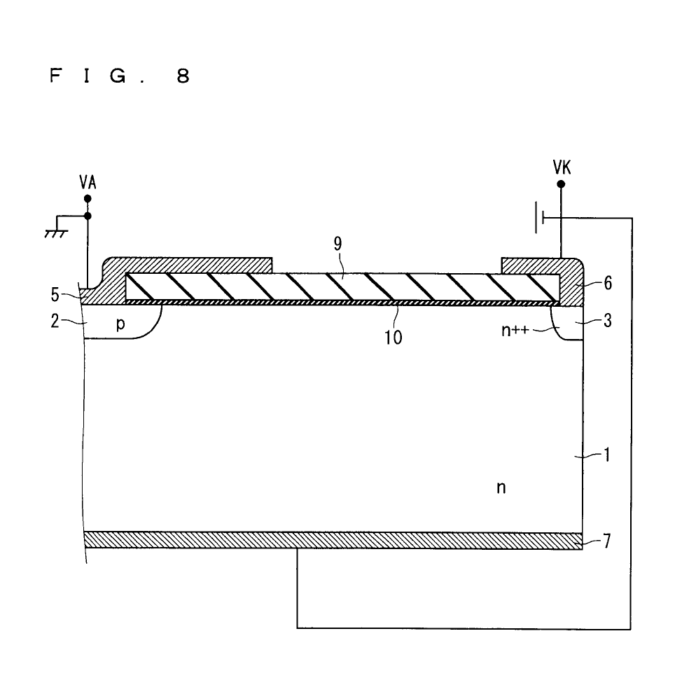

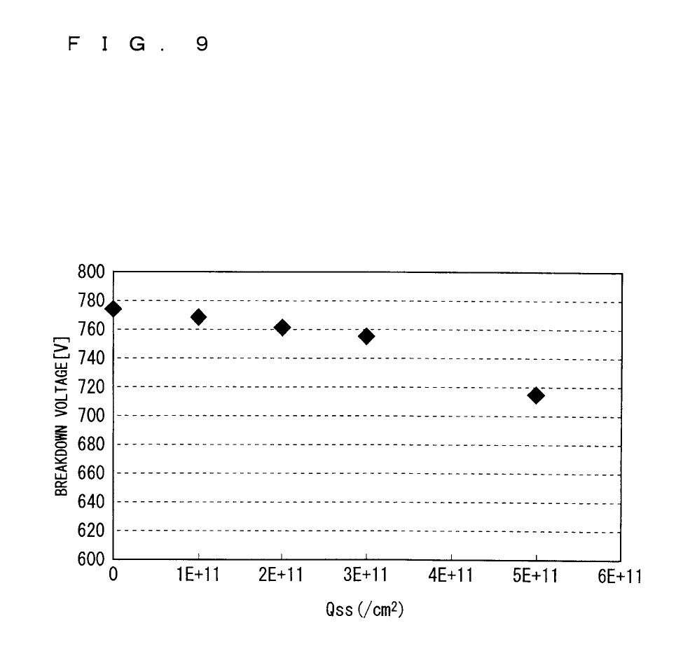

In contrast to this, as to the high breakdown voltage semiconductor device shown in FIG. 1, there are shown simulation results of the electric field distribution (FIG. 6) of the part in the vicinity of a curved part of the end of the p-type anode region 2, which is A-A′ of FIG. 1, in the blocking state (during application of 500 V) and the electric field distribution (FIG. 7) of the part in the vicinity of the end of the field plate, which is B-B′ of FIG. 1, in the blocking state (during application of 500 V). Here, in the high breakdown voltage semiconductor device shown in FIG. 1, the low dielectric constant oxide film 9 is used in place of the field oxide film 4, and a film having a dielectric constant of 2.0 and a thickness of 1.0 μm is used as the low dielectric constant oxide film 9.

It is revealed that by reducing a dielectric constant of an oxide film under the field plate, an electric field in the vicinity of the end of the field plate is mitigate and does not reach 2.5×10⁵ V/cm that is a critical electric field of silicon.

As described above, by reducing a dielectric constant of an oxide film under a field plate, the electric field in the vicinity of the end of the field plate can be mitigated without increasing a thickness of the oxide film, which makes it possible to suppress a gap in a wafer process while keeping a breakdown voltage of a high breakdown voltage semiconductor device.

Note that while a silicon oxide film doped with fluorine is described as the low dielectric constant oxide film 9 having a low dielectric constant in the first preferred embodiment. it may be an insulating film whose dielectric constant is smaller than 3.9 that is a dielectric constant of a silicon oxide film by causing a silicon oxide film generally used as an insulating film under a field plate to contain another element. Note that also in this case, the low dielectric constant oxide film 9 needs to be an inorganic insulating film using a silicon oxide film as a base so as to withstand heat treatment at high temperature performed thereafter, and an organic insulating film of, for example, polyimide cannot be used.

Similar effects can be obtained by using, as the n-type semiconductor substrate 1 according to the first preferred embodiment of the present invention, not only a silicon substrate, but also other semiconductor substrates such as a SiC substrate and a GaN substrate.

(A-3. Effects)

According to the first preferred embodiment of the present invention, the semiconductor device includes: the low dielectric constant oxide film 9 as an inorganic oxide film that is selectively formed on the n-type semiconductor substrate 1 as a semiconductor substrate of a fist conductivity type; and the anode electrode 5 and the anode electrode 6 as electrode layers formed on the n-type semiconductor substrate 1 so as to sandwich the low dielectric constant oxide film 9 therebetween. The low dielectric constant oxide film 9 is doped with an element for reducing a dielectric constant, whereby it is possible to keep a device breakdown voltage with a thin low dielectric constant oxide film 9 to reduce a gap in a wafer process.

Further, according to the first preferred embodiment of the present invention, in the semiconductor device, the low dielectric constant oxide film 9 as an inorganic oxide film is a silicon oxide film, and an element is fluorine. Accordingly, it is possible to form an insulating film that is an oxide film capable of withstanding heat treatment at high temperature and having a lower dielectric constant.

Further, according to the first preferred embodiment of the present invention, in the semiconductor device, it is possible to achieve higher breakdown voltage when the n-type semiconductor substrate 1 is a SiC substrate or a GaN substrate.

(B. Second Preferred Embodiment)

(B-1. Configuration)

FIG. 8 is a cross-sectional view showing the configuration of a junction termination of a high breakdown voltage semiconductor device according to a second preferred embodiment of the present invention. Note that for the sake of convenience, an activation region of a diode is shown.

The breakdown voltage of a high breakdown voltage semiconductor device using the field plate structure is dependent on an amount of interface charge (Qss) of a semiconductor substrate. Here, the interface refers to an interface between a semiconductor substrate and an oxide film.

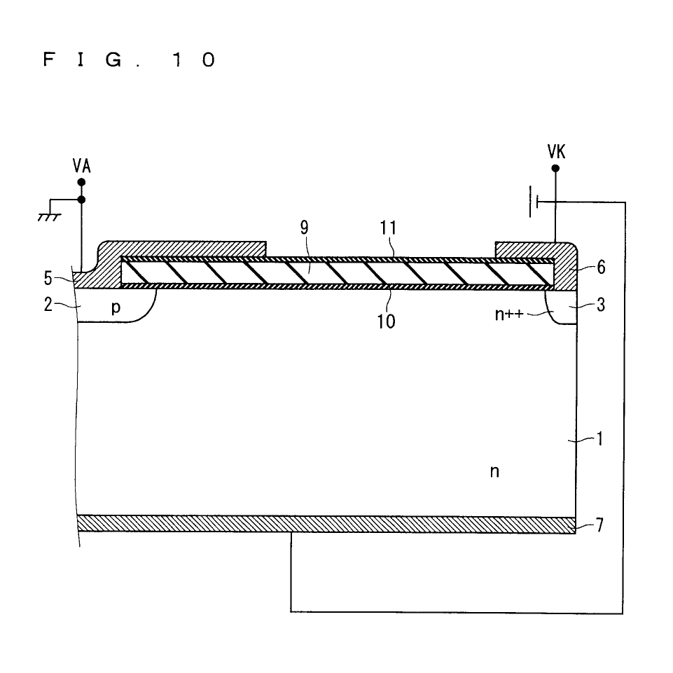

FIG. 9 shows simulation results of the dependence of the breakdown voltage of the high breakdown voltage semiconductor device shown in FIG. 8 on an amount of interface charge of a semiconductor substrate. Note that the concentration of the p-type anode region 2 is 2.0×10¹⁷ atoms/cm², the depth of the region being an interface is 7 μm, and the concentration of the n-type semiconductor substrate 1 is 2.0×10¹⁴ atoms/cm³.

FIG. 9 reveals that the breakdown voltage of a high breakdown voltage semiconductor device becomes lower as the amount of interface charge increases. This means that an amount of interface charge needs to be suppressed for improving the breakdown voltage of a semiconductor device.

The amount of interface charge is highly dependent on the method of forming an oxide film formed on a semiconductor substrate as an insulating film. For example, in a case of using a silicon semiconductor substrate, the thermal oxide film 10 formed by subjecting silicon to thermal oxidation can most suppress and stabilize the interface charge. Therefore, it is possible to reduce the dielectric constant of an oxide film while suppressing an amount of interface charge by providing a multi-layered structure in which the thermal oxide film 10 and the low dielectric constant oxide film 9 are laminated as the insulating film under the field plate in order from the n-type semiconductor substrate 1.

(B-2. Effects)

According to the second preferred embodiment of the present invention, the semiconductor device further includes the thermal oxide film 10 between the n-type semiconductor substrate l and the low dielectric constant oxidation film 9 as an inorganic oxidation film. Accordingly, it is possible to reduce a dielectric constant of the oxide film on the n-type semiconductor substrate 1 while suppressing an amount of interface charge, and thus a semiconductor device having high breakdown voltage and high reliability can be achieved.

(C. Third Preferred Embodiment)

(C-1. Configuration)

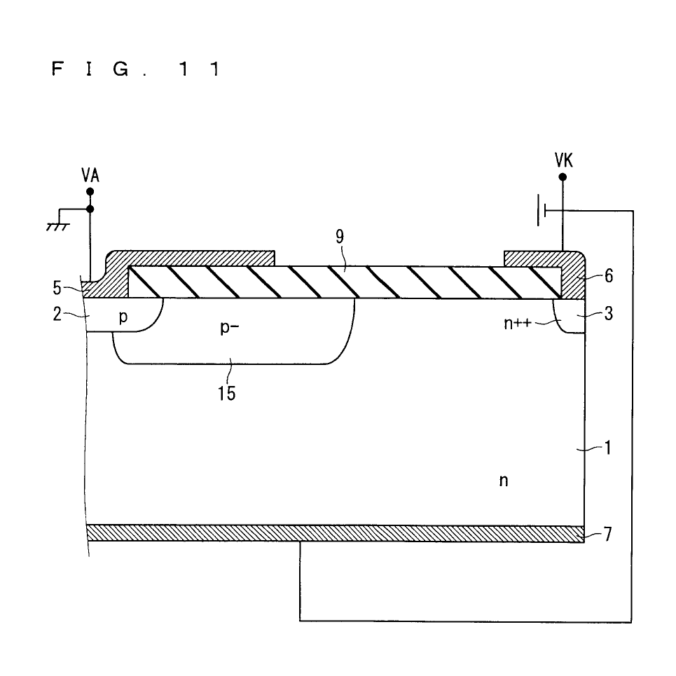

FIG. 10 is a cross-sectional view showing the configuration of a junction termination of a high breakdown voltage semiconductor device according to a third preferred embodiment of the present invention. Note that for the sake of convenience, an activation region of a diode is shown.

Differently from the first preferred embodiment of the present invention, an insulating film under the field plate has the multi-layered structure in which the thermal oxide film 10, the low dielectric constant oxide film 9, and a CVD insulating film 11 being a film deposited by plasma CVD are laminated from the semiconductor substrate side. Other configuration is similar to that of the first preferred embodiment, and thus description thereof is omitted.

Note that as described in the first preferred embodiment, an oxide film doped with impurities such as a silicon oxide film doped with fluorine is widely used as the low dielectric constant oxide film 9.

(C-2. Operation)

In manufacturing a power semiconductor device, it is typically required to perform thermal treatment at high temperature of 1,000° C. or more. This causes a problem that impurities (for example, fluorine) doped into the low dielectric constant oxide film 9 escape on that occasion, leading to an increase in dielectric constant of the low dielectric constant oxide film 9.

Accordingly, the impurities doped into the low dielectric constant oxide film 9 in the course of the process is prevented from escaping by covering an upper layer of the low dielectric constant oxide film 9 with the CVD insulating film 11, which suppresses an increase in dielectric constant.

(C-3. Effects)

According to the third preferred embodiment of the present invention, the semiconductor device further includes the CVD insulating film 11 on the low dielectric constant oxide film 9 as an inorganic oxide film. Accordingly, it is possible to prevent the impurities doped into the low dielectric constant oxide film 9 in the course of process (high temperature treatment such as annealing) from escaping, which prevents an increase in dielectric constant.

(D. Fourth Preferred Embodiment)

(D-1. Configuration)

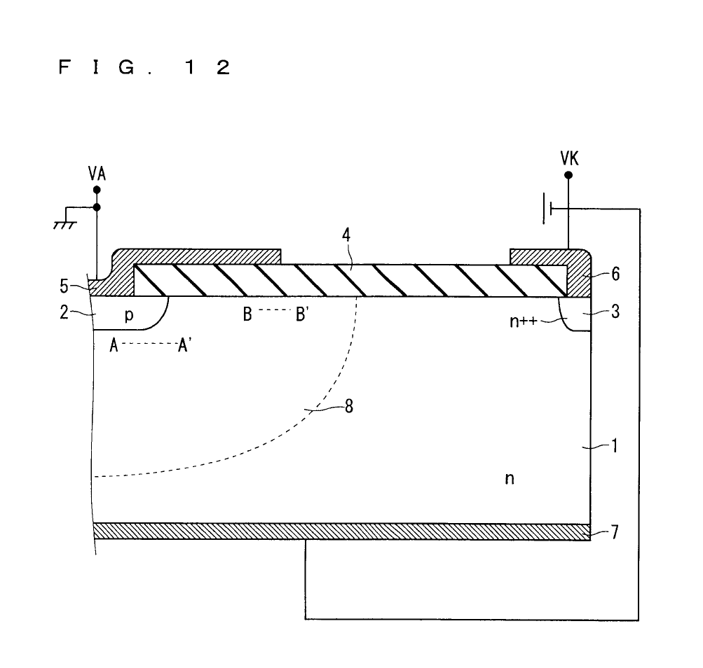

FIG. 11 is a cross-sectional view showing the configuration of a junction termination of a high breakdown voltage semiconductor device according to a fourth preferred embodiment of the present invention. Note that for the sake of convenience, an activation region of a diode is shown.

The fourth preferred embodiment is different from the first preferred embodiment in the RESURF structure in which a p-RESURF region 15 having a low impurity concentration of approximately 1.0×10¹⁶ atoms/cm³ is provided so as to be in contact with the p-type anode region 2. That is, contrary to the p-type anode region as a first impurity region, which is formed on the surface of the n-type semiconductor substrate 1 so as to be in contact with the anode electrode 5, there is further provided the p-RESURF region 15 as a second impurity region having a lower concentration compared with the p-type anode region 2, which is formed to he adjacent to the p-type anode region 2 on the surface of the n-type semiconductor substrate 1 under the low dielectric constant oxide film 9.

Effects similar to those of the first preferred embodiment are obtained with the RESURF structure not with the field plate structure.

(D-2. Effects)

According to the fourth preferred embodiment of the present invention, the semiconductor device further includes: the p-type anode region 2 as a first impurity region of a second conductivity type that is formed so as to be in contact with the anode electrode 5 as the electrode layer on the surface of the n-type semiconductor substrate 1; and the p-RESURF region 15 as a second impurity region of a second conductivity type having a lower concentration than that of the p-type anode region 2, which is formed so as to be adjacent to the p-type anode region 2 on the surface of the n-type semiconductor substrate l under the low dielectric constant oxide film as an inorganic oxide film. Accordingly, even when the field plate structure is not provided, it is possible to reduce a gap in a wafer process while keeping a breakdown voltage.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
an inorganic oxide film selectively formed on a semiconductor substrate of a first conductivity type; and
electrode layers formed on said semiconductor substrate so as to sandwich said inorganic oxide film therebetween,
wherein said inorganic oxide film is doped with an element for reducing a dielectric constant.

2. The semiconductor device according to claim 1, wherein:
said inorganic oxide film is a silicon oxide film; and
said element is fluorine.

3. The semiconductor device according to claim 1, further comprising a thermal oxide film between said semiconductor substrate and said inorganic oxide film.

4. The semiconductor device according to claim 1, further comprising a CVD insulating film on said inorganic oxide film.

5. The semiconductor device according to claim 1, further comprising:
a first impurity region of a second conductivity type formed on a surface of said semiconductor substrate so as to be in contact with said electrode layer; and
a second impurity region of a second conductivity type formed on said surface of said semiconductor substrate under said inorganic oxide film so as to be in adjacent to said first impurity region and having a concentration lower than that of said first impurity region.

6. The semiconductor device according to claim 1, wherein said semiconductor substrate is a SiC substrate or a GaN substrate.
